(19) United States
(12) Patent Application Publication
(10) Pub. No.: US 2022/0274452 A1
(43) Pub. Date: Sep. 1, 2022

(54) TIRE PHYSICAL INFORMATION ESTIMATION SYSTEM

(71) Applicant: TOYO TIRE CORPORATION, Itami-shi (JP)

(72) Inventor: Hiroshige HASEGAWA, Itami-shi (JP)

(21) Appl. No.: 17/698,255

(22) Filed: Mar. 18, 2022

Related U.S. Application Data
(63) Continuation of application No. PCT/JP2020/032923, filed on Aug. 31, 2020.

(30) Foreign Application Priority Data
Sep. 18, 2019 (JP) 2019-169563

(51) Int. Cl. B60C 23/06; B60C 23/04; B60C 23/20; G06N 3/08

(52) U.S. Cl. CPC B60C 23/064; B60C 23/0488; B60C 23/20; B60C 23/0447; G06N 3/08; B60C 2200/04

(57) ABSTRACT

A tire physical information estimation system includes a physical information estimation unit and a data acquisition unit. The physical information estimation unit includes a learning type arithmetic model including an input layer through an output layer to estimate physical information related to a tire produced in association with movement of the tire. The data acquisition unit acquires input data input to the input layer. The arithmetic model includes a feature extraction unit that performs a convolution operation in an operation halfway between the input layer and the output layer to extract a feature amount.

### CROSS-REFERENCE TO RELATED APPLICATION

This application is a continuation of application No. PCT/JP2020/032923, filed on Aug. 31, 2020, and claims the benefit of priority from the prior Japanese Patent Application No. 2019-169563, filed on Sep. 18, 2019, the entire contents of which are incorporated herein by reference.

### BACKGROUND OF THE INVENTION

### 1. Field of the Invention

The present invention relates to a tire physical information estimation system.

### 2. Description of the Related Art

Generally, methods using vehicle information such as acceleration or engine torque of a vehicle for estimation of a coefficient of friction between a tire and a road surface are known.

JP 2015-081090 A discloses a road surface friction estimation system according to the related art. The road surface friction estimation system uses a plurality of tire load estimation sensors attached to a plurality of tires of a vehicle. The load and slip angle of each tire are estimated from sensor data. The vehicle acceleration and yaw rate operation parameter are acquired from a plurality of vehicle CAN bus sensors, and the dynamic observer model calculates estimated values of force in the lateral and vertical directions in each of the plurality of tires. The estimated value individual wheel force is calculated from the estimated values of force in the lateral and vertical direction in each tire. Model-based estimated values of friction are generated from the estimated value of dynamic slip angle in each tire and the estimated value of individual wheel force in each of the plurality of tires.

### SUMMARY OF THE INVENTION

For estimation of tire force, the road surface friction estimation system of JP 2015-081090 A has to use a dynamic observer model such as a 4-wheel vehicle model based on the vehicle acceleration and yaw rate operation parameter from the vehicle side. Further, the road surface friction estimation system uses a neural network for estimation of a value of friction, but the volume of computation will be so large that it might be difficult to estimate physical information related to the tire such as the tire force and coefficient of friction on the road surface in real time.

The present invention addresses the above-described issue, and a purpose thereof is to provide a tire physical information estimation system capable of estimating physical information related to a tire in real time.

An embodiment of the present invention relates to a tire physical information estimation system. The tire physical information estimation system includes: a physical information estimation unit that includes a learning type arithmetic model including an input layer through an output layer to estimate physical information related to a tire produced in association with movement of the tire; and a data acquisition unit that acquires input data input to the input layer, wherein the arithmetic model includes a feature extraction unit that performs a convolution operation in an operation halfway between the input layer and the output layer to extract a feature amount.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a schematic diagram showing an outline of a tire physical information estimation system according to an embodiment;

FIG. 2 is a block diagram showing a functional configuration of the tire physical information estimation system according to the embodiment;

FIG. 3 is a schematic diagram showing a configuration of the arithmetic model;

FIG. 4 is a schematic diagram for explaining an exemplary operation in the arithmetic model;

FIG. 5 is a flowchart showing a sequence of steps of the tire physical information estimation process performed by the tire physical information estimation device;

FIG. 6 is a graph showing an example of acceleration data as input data;

FIGS. 7A, 7B, 7C and 7D are graphs showing an example of data from the convolution operation;

FIGS. 8A, 8B, 8C and 8D are graphs showing an example of data from the pooling operation;

FIGS. 9A, 9B, 9C and 9D are graphs showing an example of results of the fully-connected operation; and

FIG. 10 is a block diagram showing a functional configuration of the tire physical information estimation system according to a variation.

### DETAILED DESCRIPTION OF THE INVENTION

The invention will now be described by reference to the preferred embodiments. This does not intend to limit the scope of the present invention, but to exemplify the invention.

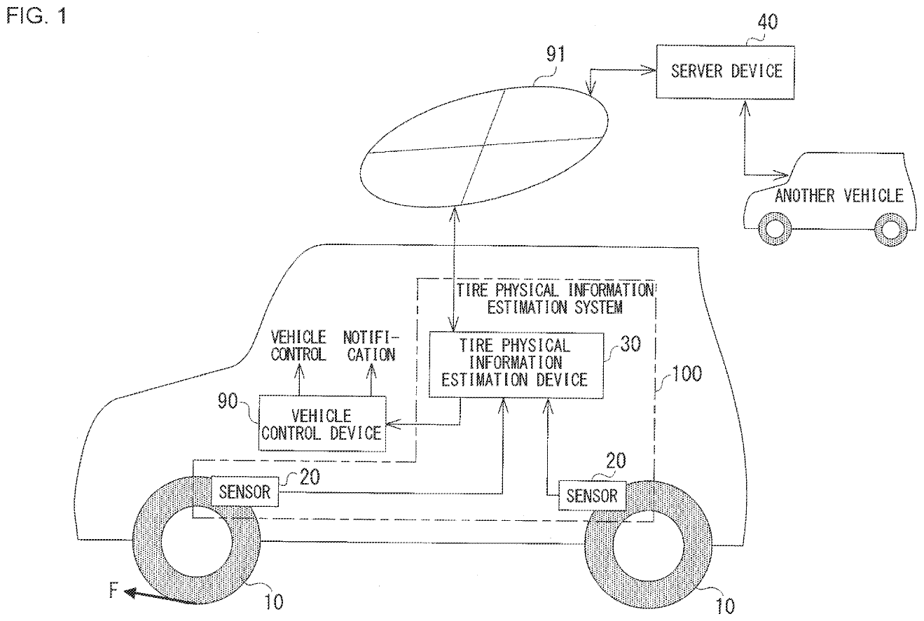

Hereinafter, the invention will be described based on a preferred embodiment with reference to FIG. 1 through 10. Identical or like constituting elements and members shown in the drawings are represented by identical symbols and a duplicate description will be omitted as appropriate. The dimension of members in the drawings shall be enlarged or reduced as appropriate to facilitate understanding. Those of the members that are not important in describing the embodiment are omitted from the drawings.

### Embodiment

FIG. 1 is a schematic diagram showing an outline of a tire physical information estimation system 100 according to an embodiment. The tire physical information estimation system 100 includes a sensor 20 provided in a tire 10 and a tire physical information estimation device 30. Further, the tire physical information estimation system 100 may include a server device 40 that acquires and collects, via a communication network 91, the tire physical information such as the tire force F and coefficient of friction on the road surface estimated by the tire physical information estimation device 30.

The sensor 20 measures the physical quantity of the tire 10 such as the acceleration and strain, tire pneumatic pressure, and tire temperature of the tire 10 and outputs the measured data to the tire physical information estimation device 30. The tire physical information estimation device 30 estimates the tire physical information based on the data measured by the sensor 20. The tire physical information estimation device 30 uses the data measured by the sensor 20 for the operation to estimate the tire physical information but may acquire, from a vehicle control device 90, etc., information such as the vehicle acceleration from the vehicle side and use the information for the operation to estimate the tire physical information.

The tire physical information estimation device 30 outputs the tire physical information such as the tire force F and coefficient of friction on the road surface as estimated to, for example, the vehicle control device 90. The vehicle control device 90 uses the tire physical information input from the tire physical information estimation device 30 for, for example, estimation of braking distance, application to vehicle control, and notification of the driver of information related to the safe driving of the vehicle. The vehicle control device 90 can also use map information, weather information, etc. to provide information related to the future safe driving of the vehicle. In the case the vehicle control device 90 has a function of driving the vehicle automatically, the tire physical information estimation system 100 provides the estimated tire physical information to the vehicle control device 90 as data used for vehicle speed control, etc. in automatic driving.

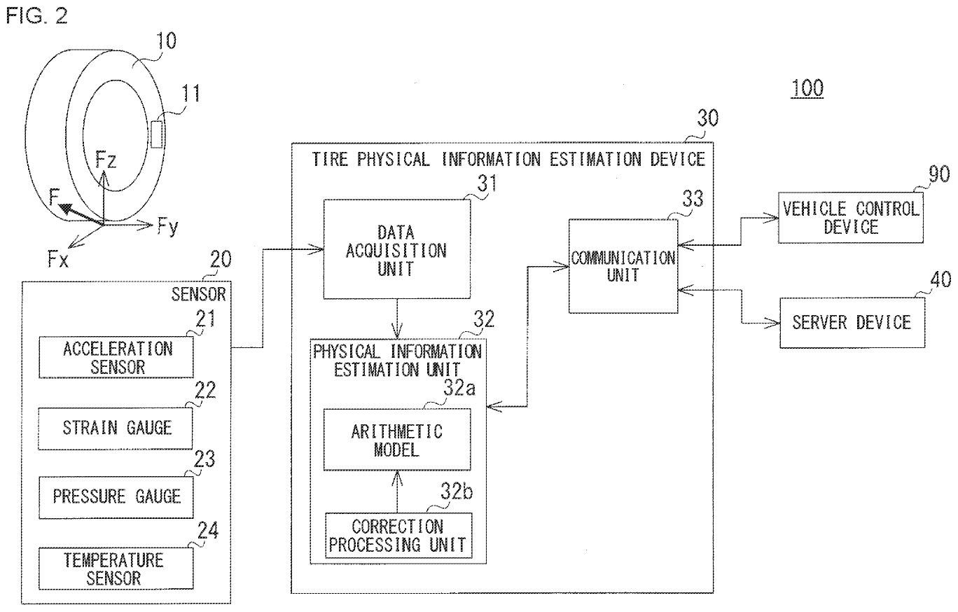

FIG. 2 is a block diagram showing a functional configuration of the tire physical information estimation system 100 according to the embodiment. The sensor 20 of the tire physical information estimation system 100 includes an acceleration sensor 21, a strain gauge 22, a pressure gauge 23, a temperature sensor 24, etc. and measures the physical quantity of the tire 10. These sensors measure, as the physical quantity of the tire 10, the physical quantity related to the deformation and movement of the tire 10.

The acceleration sensor 21 and the strain gauge 22 move mechanically along with the tire 10 and measure the acceleration and amount of strain produced in the tire 10, respectively. The acceleration sensor 21 is provided in, for example, the tread, side, and bead of the tire 10, in the wheel, etc. and measures the acceleration in the three axes, i.e., the circumferential, axial, and radial directions of the tire 10.

The strain gauge 22 is provided in the tread, side, bead, etc. of the tire 10 and measures the strain at the location of provision. Further, the pressure gauge 23 and the temperature sensor 24 are provided in, for example, the air valve of the tire 10 and measure the tire pneumatic pressure and tire temperature, respectively. The temperature sensor 24 may be provided directly in the tire 10 to measure the temperature of the tire 10 accurately. An RFID 11, etc. to which unique identification information is assigned may be attached to the tire 10 to identify each tire.

The tire physical information estimation device 30 includes a data acquisition unit 31, a physical information estimation unit 32, and a communication unit 33. The tire physical information estimation device 30 is an information processing device such as a personal computer (PC). The units in the tire physical information estimation device 30 can be realized in hardware by an electronic element such as a CPU of a computer, a machine component or the like, and in software by a computer program or the like. Functional blocks realized through collaboration among them are depicted here. Accordingly, those skilled in the art will understand that these functional blocks can be realized in various forms by a combination of hardware and software.

The data acquisition unit 31 acquires, by wireless communication, etc., information on the acceleration, strain, pneumatic pressure, and temperature measured by the sensor 20. The communication unit 33 communicates wirelessly with an external device such as the vehicle control device 90 and the server device 40 by wire or wirelessly. The communication unit 33 transmits the physical quantity of the tire 10 measured by the sensor 20 and the tire physical information etc. estimated for the tire 10, etc. to the external device via a communication line (e.g., a control area network (CAN)), the Internet, etc.).

The physical information estimation unit 32 includes an arithmetic model 32a and a correction processing unit 32b, inputs the information from the data acquisition unit 31 to the arithmetic model 32a, and estimates the tire physical information such as the tire force F and coefficient of friction on the road surface. As shown in FIG. 2, the tire force F has components in the three axial directions, i.e., a longitudinal force Fx in the longitudinal direction of the tire 10, a lateral force Fy in the lateral direction, and a load Fz in the vertical direction. The physical information estimation unit 32 may calculate all of these components in the three axial directions, calculate one of the components, or an arbitrary combination of two components.

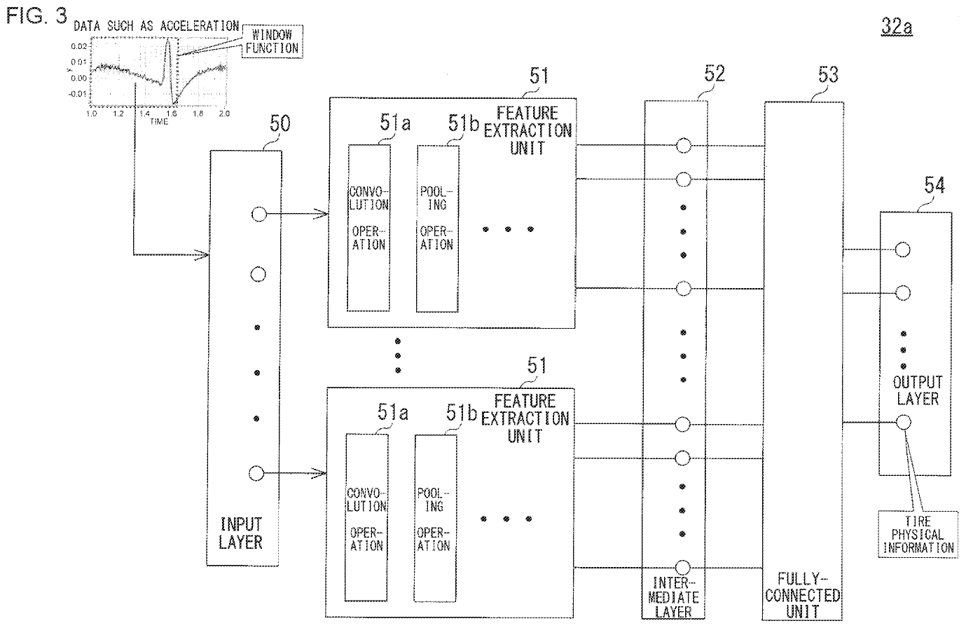

The arithmetic model 32a uses a learning type model such as a neural network. FIG. 3 is a schematic diagram showing a configuration of the arithmetic model 32a. The arithmetic model 32a is of a convolutional neural network (CNN) type and is a learning type model provided with convolution operation and pooling operation used in the so-called LeNet, which is a prototype of CNN. The arithmetic model 32a includes an input layer 50, a feature extraction unit 51, an intermediate layer 52, a fully-connected unit 53, and an output layer 54, and performs operations on a processor (such as a CPU, etc.). The time-series data acquired by the data acquisition unit 31 is input to the input layer 50. The feature extraction unit 51 extracts a feature amount by using a convolution operation 51a and a pooling operation 51b and transmits the feature amount to the nodes of the intermediate layer 52.

The fully-connected unit 53 connects the nodes of the intermediate layer 52 to the respective nodes of the output layer 54 via fully-connected paths on which weighted liner operation is performed. In addition to a linear operation, the fully-connected unit 53 may perform a non-linear operation by using an activating function, etc.

The tire physical information such as the tire force F in the three axial directions and coefficient of friction on the road surface is output to the nodes of the output layer 54. The output layer 54 may output the tire force F in the three axial directions, output the coefficient on the road surface, or output both the tire force and the coefficient of friction on the road surface.

In the estimation of the coefficient of friction on the road surface, the output layer 54 may output an estimated value of the coefficient of friction on the road surface. Alternatively, the coefficient of friction on the road surface may be grouped into a category such as dry, wet, snowy, or frozen, and the output layer 54 may output which category is applicable.

By causing the arithmetic model 32a to learn the tire axial force measured in the tire 10 as training data, a model having a high precision of estimation of the tire force F can be obtained. The configuration (e.g., the number of layers) and weighting in the fully-connected unit 53 of the arithmetic model 32a change basically in accordance with the specification of the tire 10. The arithmetic model 32a can be trained in rotation tests in the tires 10 (including the wheel) with different specifications. It should however be noted that it is not necessary to strictly train the arithmetic model 32a for each specification of the tire 10. By training and building the arithmetic model 32a for different types (e.g., the tire for passenger car and the tire for trucks) to make it possible to estimate the tire force F within a predetermined margin of error, one arithmetic model 32a may be shared by the tires 10 encompassed by multiple specifications so that the number of arithmetic models is reduced. Further, the arithmetic model 32a can be trained by mounting the tire 10 to an actual vehicle and test driving the vehicle. The specification of the tire 10 includes information related to tire performance such as tire size, tire width, tire profile, tire strength, tire outer diameter, road index, and year/month/date of manufacturing.

The arithmetic model 32a may be trained by conducting rotation tests, changing the coefficient of friction on the ground surface touched by the tire 10. Further, the arithmetic model 32a may be trained by mounting the tire 10 to an actual vehicle and test driving the vehicle on road surfaces with different coefficients of friction. The arithmetic model 32a is a trained model that is trained by the output value from the output layer 54 to be matched with the measured tire force F or the measured coefficient of friction on the road surface between the tire 10 and the road surface.

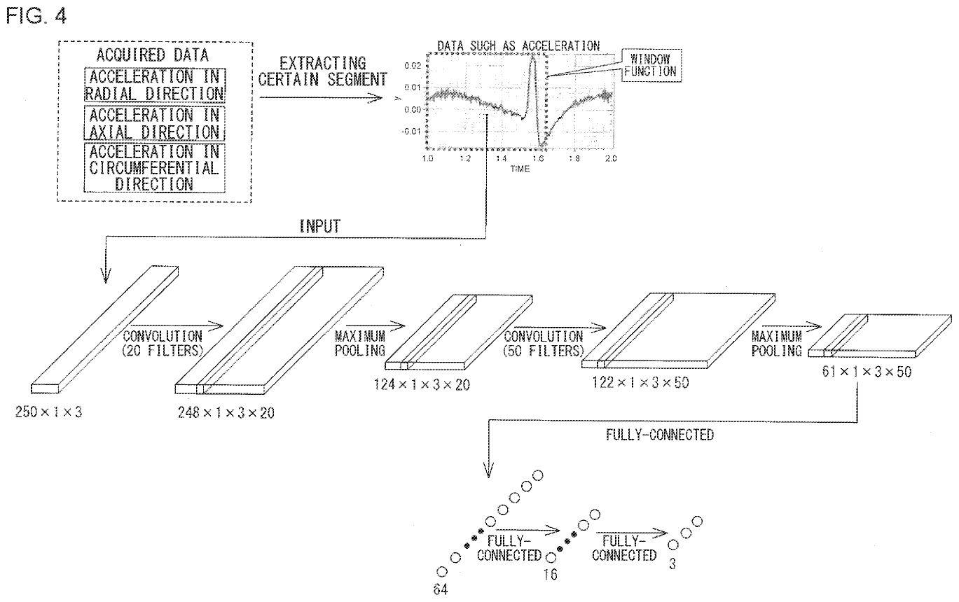

FIG. 4 is a schematic diagram for explaining an exemplary operation in the arithmetic model 32a. Referring to FIG. 4, acceleration data in the three axial directions is used as the input data input to the arithmetic model 32a. The time-series acceleration data is measured by the sensor 20. Data for a predetermined time segment is extracted by a window function for use as the input data. For example, the input data may be 250 items of acceleration data included in a predetermined time segment for each axis. Acceleration measured in the tire 10 exhibits periodicity per rotation of the tire 10. The time segment of input data extracted by the window function may be a period of time corresponding to the period of rotation of the tire 10 so that the input data itself is imparted with a periodicity. The window function may extract input data in a time segment shorter or longer than one rotation of the tire 10. The arithmetic model 32a can be trained so long as the extracted input data at least includes periodical information.

The arithmetic model 32a uses, for example, 20 filters for the input data to perform the first convolution operation and obtains 248×1 (data size)×3 (the number of channels: corresponding to the acceleration data for the three axes)×20 (the number of filters) items of data from the convolution operation. The arithmetic model 32a performs the convolution operation by moving the filter relative to the time series input data such as acceleration data. The filter length is indicated to be 3 but may be set to be 1-5 as appropriate. The convolution operation is performed such that, of the time series input data, data as long as the continuous filter length (e.g., A1, A2, A3) is multiplied by the values (f1, f2, f3) in the filters, respectively. The values obtained by the multiplication are added up so as to obtain A1×f1+A2×f2+A3×f3. Zero padding, whereby “0” data is appended to the end of the input data, may be performed to perform the convolution operation. The amount of movement of the filter in the convolution operation is, normally, one item of input data but may be modified as appropriate to reduce the scale of the arithmetic model 32a.

The data from the first convolution operation is subjected to the first maximum pooling operation to obtain 124×3×20 items of data. After the maximum pooling operation is performed, the second convolution operation is performed by using, for example, 50 filters to obtain 122×3×50 items of data. Further, the second maximum pooling operation is performed to obtain 61×3×50 items of feature amount, which is output to the nodes of the intermediate layer 52.

The number of nodes in the intermediate layer 52 is 61×3×50, which are input to the fully-connected unit 53 comprised of a single or multiple layers. The operation proceeds until the data is input to the output layer 54. In the output layer 54, the tire force F in the three axial directions is presented, for example.

The correction processing unit 32b corrects the arithmetic model 32a based on the status of the tire 10. An alignment error is produced when the tire 10 is mounted to the vehicle. The physical property such as rubber hardness changes with time so that wear progresses as the tire is driven. The status of the tire 10, which include elements such as the alignment error, physical property, and wear, changes depending on the status of use, creating an error in the calculation of the tire force F by means of the arithmetic model 32a. The correction processing unit 32b performs a process of adding a correction term determined by the status of the tire 10 to the arithmetic model 32a in order to reduce an error in the arithmetic model 32a.

The server device 40 acquires, from the tire physical information estimation device 30, the physical quantity of the tire 10 measured by the sensor 20 and the tire physical information such as the tire force F and coefficient of friction on the road surface estimated for the tire 10. The server device 40 may collect, from a plurality of vehicles, the physical quantity measured in the tire 10 and the tire physical information, etc. estimated by the tire physical information estimation device 30.

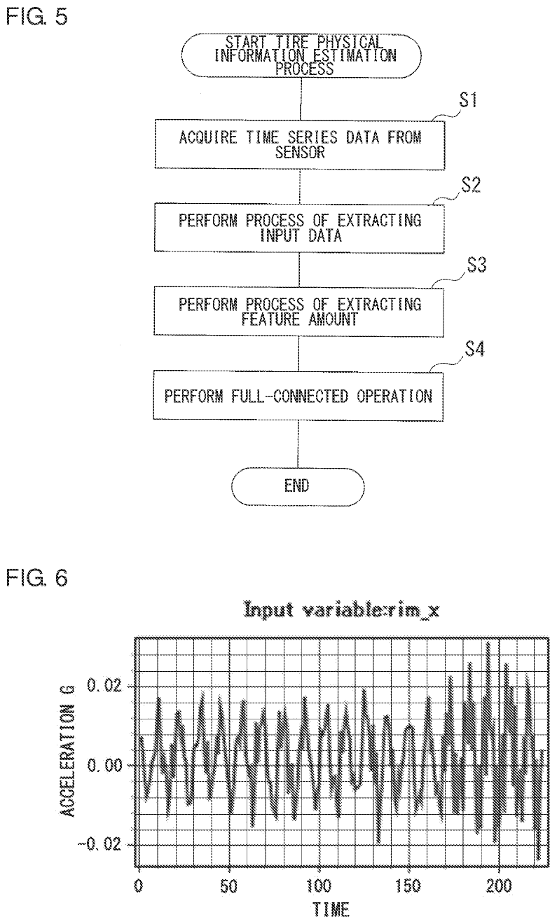

A description will now be given of the operation of the tire physical information estimation system 100. FIG. 5 is a flowchart showing a sequence of steps of the tire physical information estimation process performed by the tire physical information estimation device 30. The tire physical information estimation device 30 acquires the physical quantity such as the acceleration, strain, tire pneumatic pressure, tire temperature, etc. of the tire 10 measured by the sensor 20 by means of the data acquisition unit 31 (S1).

The physical information estimation unit 32 extracts input data in a predetermined time segment from the data acquired by the data acquisition unit 31 (S2). FIG. 6 is a graph showing an example of acceleration data as input data. The acceleration data shown in FIG. 6 is time series data in one axial direction of the three axial directions. The graph shows that the acceleration produced in the tire 10 changes as the tire 10 is rotated.

For estimation of tire physical information, acceleration data for at least one axis (e.g., the circumferential direction) is necessary as input data. Further, acceleration data for two axes, i.e., the circumferential direction and axial direction of the tire 10, may be used as input data, or acceleration data for three axes may be used as input data for estimation of tire physical information. Further, the time series data for at least one of the strain, tire pneumatic pressure, tire temperature of the tire 10 may be included in the input data.

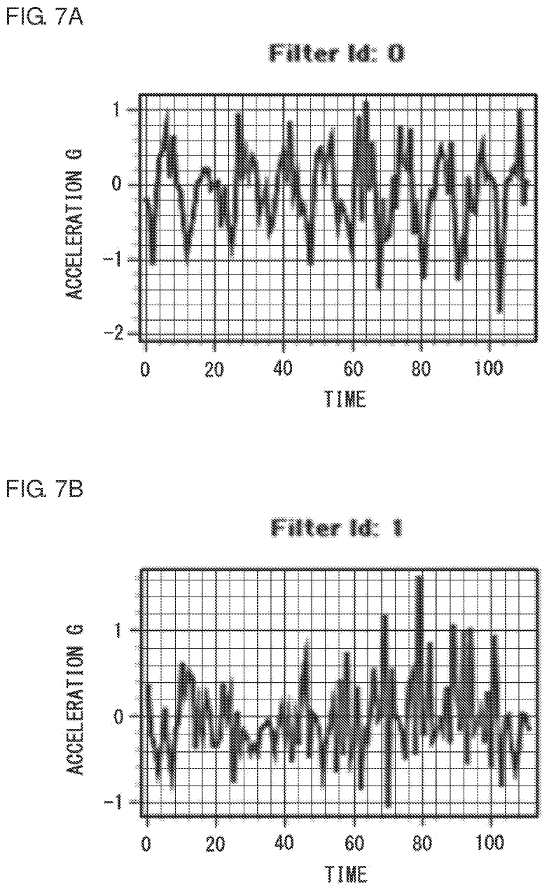

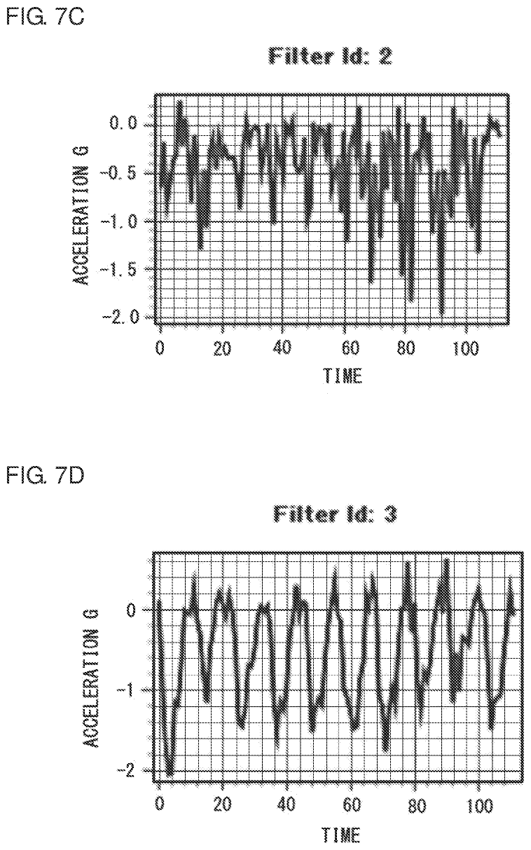

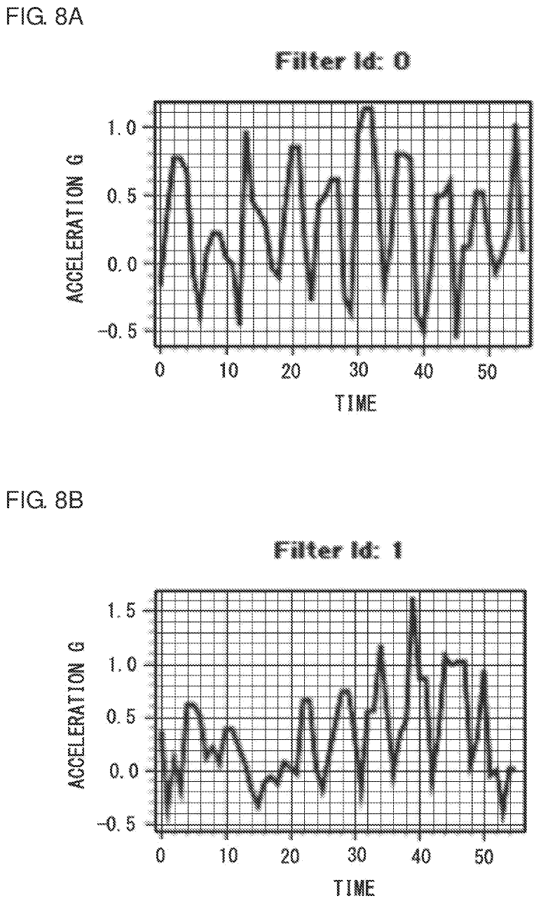

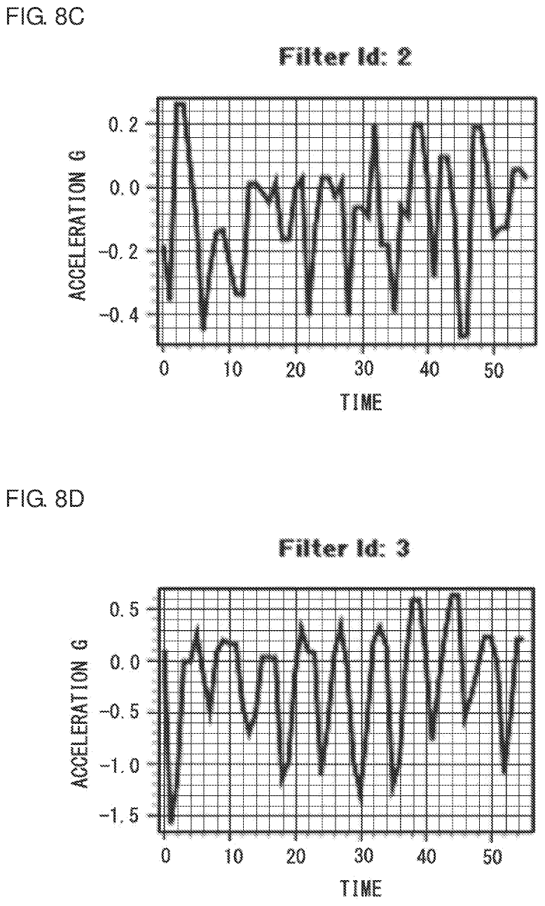

The feature extraction unit 51 of the arithmetic model 32a performs a process of extracting the feature amount by the convolution operation 51a and the pooling operation 51b on the input data (S3). FIGS. 7A to 7D are graphs showing an example of data from the convolution operation, and FIGS. 8A to 8D are graphs showing an example of data from the pooling operation.

FIGS. 7A to 7D show results of the convolution operation performed by using four different filters, but the number of filters is not limited to this. The data shown in FIGS. 8A to 8D are data from the pooling operation on the data from the convolution operation shown in FIGS. 7A to 7D, respectively. The pooling operation shown in FIGS. 8A to 8D is a scheme for extracting the maximum value of two items of data, but the number of items of data subject to the pooling operation and the scheme of pooling are not limited to these. The pooling operation makes it possible to perform the operation in the arithmetic model 32a such that the feature amount is extracted, and, at the same time, the data volume is reduced.

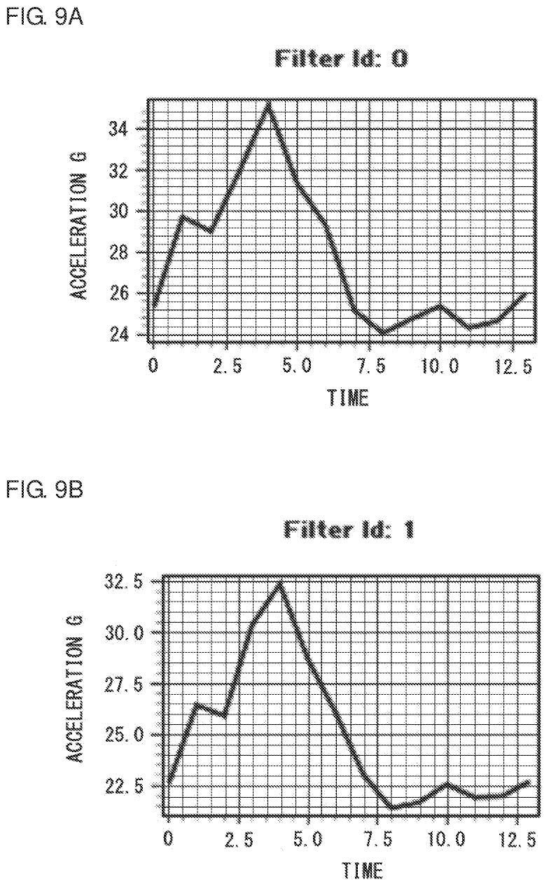

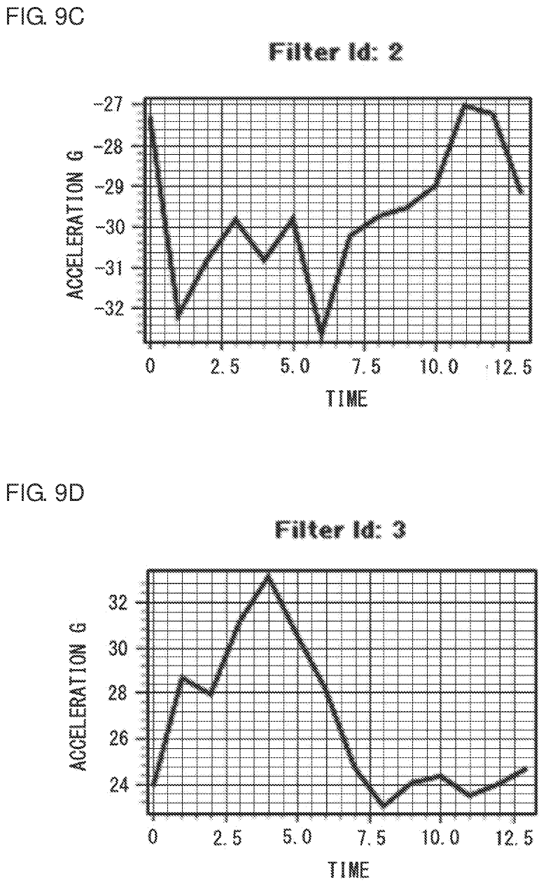

The fully-connected unit 53 of the arithmetic model 32a performs a fully-connected operation on the feature amount extracted by the feature extraction unit 51 and input to the nodes of the intermediate layer 52 (S4). FIGS. 9A to 9D are graphs showing an example of results of the fully-connected operation. The data shown in FIGS. 9A to 9D are data from the fully-connected operation on the data from the pooling operation shown in FIGS. 8A to 8D, respectively.

The fully-connected operation is performed in the direction from the intermediate layer 52 toward the output layer 54 and is a dimension reduction process whereby the number of items of data is reduced. It is assumed that parameters for weighting, etc. used in the fully-connected operation are determined as a result of training the arithmetic model 32a but are corrected by the correction processing unit 32b in accordance with the situation of the tire 10. The fully-connected operation outputs, for example, the tire physical information such as the tire force F and coefficient of friction on the road surface to the nodes of the output layer 54.

Using the arithmetic model 32a of a CNN type makes it possible to extract time series acceleration data by a window function and perform the convolution operation while moving the filter. It is therefore not necessary to align the start of operation with a specific point of time. Thus, the tire physical information estimation system 100 can estimate the tire physical information in real time according to the time series data measured by the sensor 20, by using the arithmetic model 32a of a CNN type.

The tire physical information estimation system 100 builds the arithmetic model 32a that estimates the tire physical information in real time based on the measurement data produced by the rotation of the tire 10, which is a periodical motion. The tire physical information estimation system 100 can make a computation easily in the event of a change in the tire force F etc. caused by a change in the road surface. It is therefore possible to make a prediction of, for example, an event one second after and maintain the real time performance.

Further, the tire physical information estimation system 100 can reduce the volume of operation in the fully-connected network and reduce the volume of computational processing during estimation, by extracting the feature amount.

Even if there are a plurality of types of data measured by the sensor 20 and input to the arithmetic model 32a, the tire physical information estimation system 100 can learn what values of the tire physical information, such as the tire force F and coefficient of friction on the road surface, are output in response to the plurality of types of data affected by the same phenomenon produced in the tire 10. Therefore, the precision of estimation is improved.

It is possible to build, in the tire physical information estimation system 100, an even more precise arithmetic model 32a with reduced computational cost, by using the extracted data in combination with a scheme such as a decision tree, a recurrent neural network (RNN), and a deep neural network (DNN).

### Variation

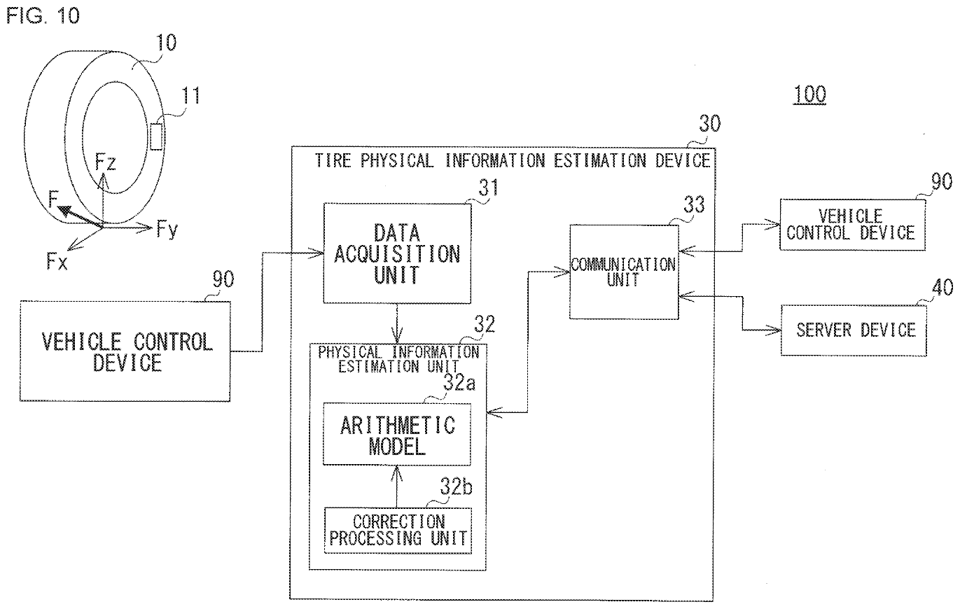

FIG. 10 is a block diagram showing a functional configuration of the tire physical information estimation system 100 according to a variation. In the variation shown in FIG. 10, the data input to the arithmetic model 32a is acquired from the vehicle control device 90. Both the data from the vehicle control device 90 and the data from the sensor 20 (see FIG. 2) can be used as the data input to the arithmetic model 32a.

For example, the vehicle control device 90 acquires, in the digital tachometer etc. of the vehicle, traveling data such as the traveling speed of the vehicle, acceleration in the three axial directions, and triaxial angular speed, and load data such as the weight of the vehicle and axle load applied to the axle shaft. The vehicle control device 90 outputs the traveling data and load data to the tire physical information estimation device 30.

The tire physical information estimation device 30 estimates, by means of the arithmetic model 32a, the tire physical information such as the tire force F and coefficient of friction on the road surface in response to the data input from the vehicle control device 90. The arithmetic model 32a is built while an actual vehicle is being test driven, by learning to estimate the tire physical information in response to the data input from the vehicle control device 90 in advance.

The embodiment and the variation are described above by exemplifying the tire physical information estimated by the arithmetic model 32a by the tire force F and coefficient of friction on the road surface. Alternatively, the looseness of a fastening component such as a wheel nut used to mount the tire 10 can be estimated. The vibration due to the looseness of the fastening component such as a wheel nut is reflected in the acceleration data measured in the tire 10, and so the arithmetic model 32a of a CNN type for estimating the looseness of the fastening component is built and trained by way of comparison with the tire force F. The tire physical information estimation system 100 can estimate the looseness of the fastening component of the tire 10 in real time by running the operation in the arithmetic model 32a based on the input data such as the acceleration data acquired when an actual vehicle is driven.

The sensor 20 is not limited to the sensors described with reference to FIG. 1, and a microphone provided in the tire 10 or the neighborhood thereof may be used. The arithmetic model 32a may estimate the tire physical information by using audio data collected by the microphone.

In the embodiment and the variation described above, the arithmetic model 32a of a CNN type built on the LeNet model is used. Alternatively, a model structure such as the Dense Net model, Res Net model, Mobile Net model, and Peleel Model may be used. A module structure such as Dense Block, Residual Block, Stem Block, etc. may be incorporated into the arithmetic model 32a to build the model. The model of the tire force may be such that models for the components Fx, Fy, Fx may be independent of each other. The model may be structured be such that the convolution layers and the pooling layers are integrated, and only the operations in the fully-connected layers output Fx, Fy, Fz independently.

A description will now be given of the features of the tire physical information estimation system 100 according to the embodiment. The tire physical information estimation system 100 according to the embodiment includes the physical information estimation unit 32 and the data acquisition unit 31. The physical information estimation unit 32 includes the learning type arithmetic model 32a including the input layer 50 through the output layer 54 to estimate the physical information related to the tire 10 produced in association with the movement of the tire 10. The data acquisition unit 31 acquires the input data input to the input layer 50. The arithmetic model 32a includes the feature extraction unit 51 that performs the convolution operation 51a in the operation halfway between the input layer 50 and the output layer 54 to extract the feature amount. This makes it possible for the tire physical information estimation system 100 to estimate the tire physical information such as the tire force F and coefficient of friction on the road surface in real time.

Further, the feature extraction unit 51 performs the pooling operation 51b in addition to the convolution operation. This makes it possible for the tire physical information estimation system 100 to perform the operation using the arithmetic model 32a such that the feature amount is extracted, and, at the same time, the data volume is reduced.

Further, the input data includes the acceleration data measured in the tire 10. This makes it possible for the tire physical information estimation system 100 to estimate the tire physical information such as the tire force F and coefficient of friction on the road surface in real time by measuring the acceleration produced when the tire 10 is moved by means of the acceleration sensor 21 provided in the tire 10.

Further, the input data includes the acceleration data in the vehicle to which the tire 10 is mounted. This makes it possible for the tire physical information estimation system 100 to estimate the tire physical information such as the tire force F and coefficient of friction on the road surface in real time by acquiring the acceleration data from the vehicle side.

Further, the tire physical information is a tire force produced in the tire 10. This makes it possible for the tire physical information estimation system 100 to estimate the tire force F in real time.

Further, the tire physical information is a coefficient of friction on the road surface between the tire 10 and the road surface. This makes it possible for the tire physical information estimation system 100 to estimate the coefficient of friction on the road surface in real time.

Described above is an explanation based on an exemplary embodiment. The embodiments are intended to be illustrative only and it will be understood by those skilled in the art that variations and modifications are possible within the claim scope of the present invention and that such variations and modifications are also within the claim scope of the present invention. Accordingly, the description and drawings in the specification shall be interpreted as being illustration instead of limitation.

What is claimed is:

1. A tire physical information estimation system comprising:
a sensor that measures in a tire or in a vehicle to which the tire is mounted, and generates an input data;
a physical information estimation unit that includes a learning type arithmetic model including an input layer through an output layer to estimate physical information related to the tire produced in association with movement of the tire; and
a data acquisition unit that acquires the input data input to the input layer, wherein
the arithmetic model includes a feature extraction unit that performs on a processor a convolution operation in an operation halfway between the input layer and the output layer to extract a feature amount.

2. The tire physical information estimation system according to claim 1, wherein
the feature extraction unit performs a pooling operation in addition to the convolution operation.

3. The tire physical information estimation system according to claim 2, wherein
the input data includes acceleration data measured in the tire.

4. The tire physical information estimation system according to claim 1, wherein
the input data includes acceleration data in the vehicle.

5. The tire physical information estimation system according to claim 1, wherein
the tire physical information is a tire force produced in the tire.

6. The tire physical information estimation system according to claim 1, wherein
the tire physical information is a coefficient of friction on a road surface between the tire and the road surface.

7. The tire physical information estimation system according to claim 1, wherein
the arithmetic model is a trained model that is trained by an output value from the output layer to be matched with a measured tire force or a measured coefficient of friction on a road surface between the tire and the road surface.
